(19) United States
(12) Patent Application Publication
(10) Pub. No.: US 2007/0159842 A1
(43) Pub. Date: Jul. 12, 2007

(54) Fiber optic LED decoration lights

(75) Inventor: Sedrick J. Cole, Katy, TX (US)

Correspondence Address: DOCKET CLERK, P.O. DRAWER 800889, DALLAS, TX, 75380, US

(73) Assignee: FIBER GLOW LLC, Houston, TX (US)

(21) Appl. No.: 11/495,146

(22) Filed: Jul. 28, 2006

Related U.S. Application Data
(60) Provisional application No. 60/758,074, filed on Jan. 11, 2006.

(51) Int. Cl. H01L 33/00

(52) U.S. Cl. 362/555

(57) ABSTRACT

A plurality of light units are connected to a common electrical conductor, spaced apart along a length of the conductor. Each light unit includes an enclosure comprising a housing containing a light emitting diode therein and a cap fitting over an open end of the housing. A plurality of optical fibers bundled together at one end extend through an opening in the cap, with the bundled ends arranged substantially evenly and proximate to the light emitting diode to receive light therefrom. The other ends of the optical fibers are dispersed, and light received from the light emitting diode is emitted from such dispersed other ends.

### CROSS-REFERENCE TO RELATED APPLICATION(S)

This application claims priority to U.S. Provisional Patent Application Ser. Nos. 60/758,074 filed Jan. 11, 2006. The content of the above-identified application is hereby incorporated by reference.

### TECHNICAL FIELD OF THE INVENTION

The present invention is directed, in general, to fiber optic arrangements and, more specifically, to utilizing a light emitting diode (LED) light source together with optical fibers for either decorative or utilitarian purposes.

### BACKGROUND OF THE INVENTION

Recently optical fibers have been used for decoration as a fairly new illuminating light decor, such as for holidays and/or personal use. One means of such use for optical fibers involves a single light source (typically a halogen/incandescent type light source) with one end of the optical fibers bundled together at that light source and the other ends dispersed toward a desired position, forming a tree-like structure. Such a configuration typically could not be used for other types of decorations, such as Christmas light strings, due to (a) the amount of fiber optic wire required and (b) the cumbersome use of a single incandescent light source. Moreover, the incandescent light source is generally energy inefficient, prone to damage, and poses a potential fire hazard due to the high temperature created by the bulbs.

Currently, optical fiber Christmas tree lights for artificial trees are an integral part of the tree, such that removal is not possible or practical. Thus, for example, removing the fiber optic Christmas lights from an artificial Christmas tree and placing those lights on a wreath instead cannot be accomplished as easily as with regular incandescent Christmas light strings. Most incandescent Christmas light strings can be easily placed on Christmas trees, wreaths, walls, bushes etc. without difficulty or special equipment.

There is, therefore, a need in the art for fiber optic LED decoration lights which permit more mobility/utility of decorating. It would further be advantageous for such lights to promote energy efficiency and reduce fire hazards.

### SUMMARY OF THE INVENTION

To address the above-discussed deficiencies of the prior art, it is a primary object of the present invention to provide, for use in a decorative assembly, a plurality of light units connected to a common electrical conductor, spaced apart along a length of the conductor. Each light unit includes an enclosure comprising a housing containing a light emitting diode therein and a cap fitting over an open end of the housing. A plurality of optical fibers bundled together at one end extend through an opening in the cap, with the bundled ends arranged substantially evenly and proximate to the light emitting diode to receive light therefrom. The other ends of the optical fibers are dispersed, and light received from the light emitting diode is emitted from such dispersed other ends.

The foregoing has outlined rather broadly the features and technical advantages of the present invention so that those skilled in the art may better understand the detailed description of the invention that follows. Additional features and advantages of the invention will be described hereinafter that form the subject of the claims of the invention. Those skilled in the art will appreciate that they may readily use the conception and the specific embodiment disclosed as a basis for modifying or designing other structures for carrying out the same purposes of the present invention. Those skilled in the art will also realize that such equivalent constructions do not depart from the spirit and scope of the invention in its broadest form.

Before undertaking the DETAILED DESCRIPTION OF THE INVENTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases.

### BRIEF DESCRIPTION OF THE DRAWINGS

For a more complete understanding of the present invention, and the advantages thereof, reference is now made to the following descriptions taken in conjunction with the accompanying drawings, wherein like numbers designate like objects, and in which:

FIG. 1 is an isometric view of a string of fiber optic LED decoration lights in a multi-light set up according to one embodiment of the present invention;

FIG. 2 is a perspective view of an individual fiber optic LED decoration light unit according to one embodiment of the present invention;

FIG. 3 is a perspective partial cross-sectional isometric side view of an individual fiber optic LED decoration light according to one embodiment of the present invention;

FIG. 4 is a partially exploded, detailed perspective view of the fiber optic light array out of the LED housing for an individual fiber optic LED decoration light according to one embodiment of the present invention; and

FIG. 5 is a close up view of an optional scratch/indentation pattern on the fiber optic wire to create a sparkling effect for an individual fiber optic LED decoration light according to one embodiment of the present invention.

### DETAILED DESCRIPTION OF THE INVENTION

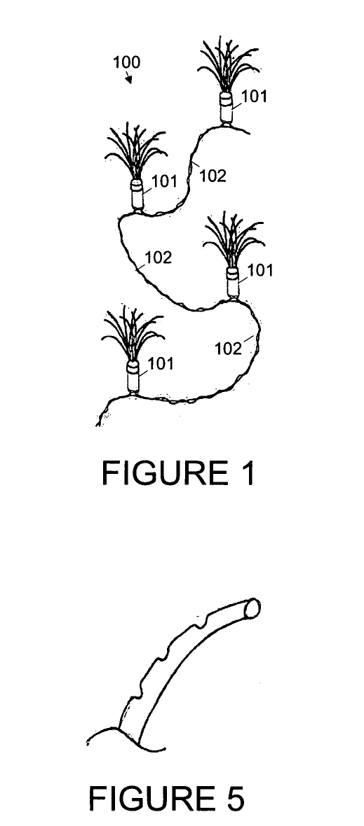

FIGS. 1 through 5, discussed below, and the various embodiments used to describe the principles of the present invention in this patent document are by way of illustration only and should not be construed in any way to limit the scope of the invention. Those skilled in the art will understand that the principles of the present invention may be implemented in any suitably arranged device.

FIG. 1 is an isometric view of a string of fiber optic light emitting diode (LED) decoration lights in a multi-light set up according to one embodiment of the present invention. The string 100 includes a plurality of fiber optic LED units 101 connected by a common electrical conductor subsystem 102, which in the exemplary embodiment is at least one twisted pair of insulated wires. The insulated wires form a closed loop terminating with a standard household electrical plug (not shown). The string 100 may further include a controller (also not shown) between the conductor subsystem 102 and such plug, such as electrical circuitry converting received alternating current (AC) power to direct current (DC) power or interrupting current through the conductor subsystem.

The string 100 includes multiple fiber optic LED decoration light units 101 spaced several inches apart. The spacing and number of fiber optic LED decoration light units 101 can consist of a single sequence or multiple, independently-operable sequences. For multiple sequences to be independently operated (e.g., so that alternate fiber optic LED decoration light units 101 are illuminated together while intervening alternate fiber optic LED decoration light units 101 are off), separate insulated wires must be provided within the conductor subsystem 102.

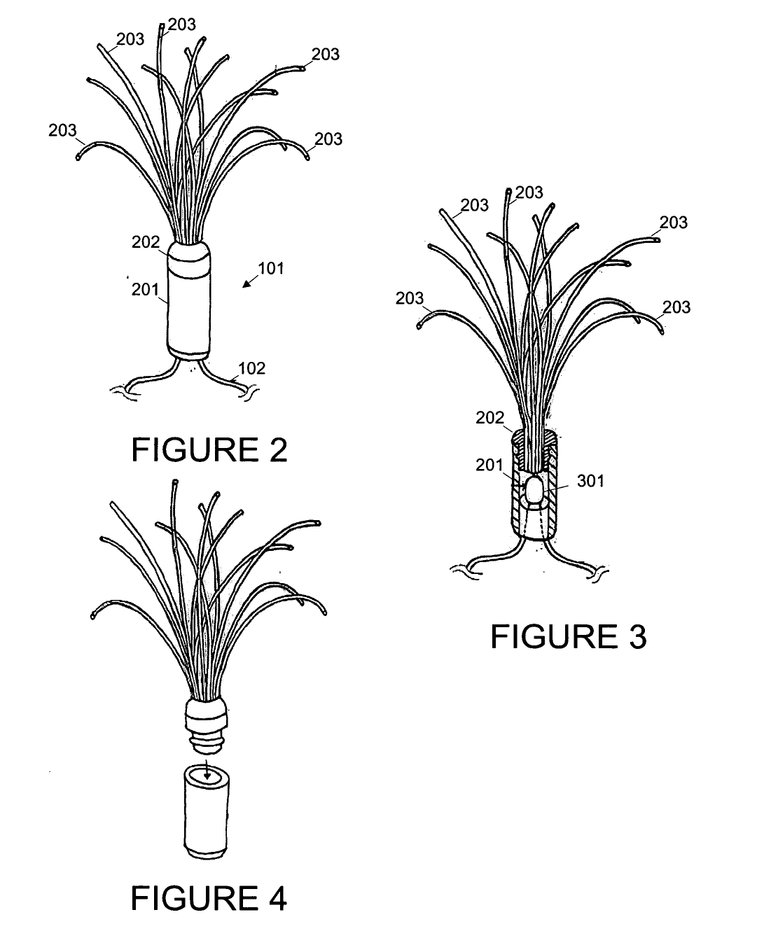

FIG. 2 is a perspective view of an individual fiber optic LED decoration light unit according to one embodiment of the present invention. The fiber optic LED decoration light unit 101, fully assembled as a single unit, includes a housing 201, a cap 202 and a plurality of bundled, unjacketed optical fibers 203. As shown, the optical fibers 203 are assembled in a bundled pattern with equal or varying lengths, extending from and through a top portion of cap 202. The ends of optical fibers 203 extend through a hole through the top of cap 202, with the ends of fibers 203 substantially aligned for receiving light from an LED within the housing 201 (not shown in FIG. 2).

FIG. 3 is a perspective partial cross-sectional isometric side view of an individual fiber optic LED decoration light according to one embodiment of the present invention. The optical fibers 203 are held together by the cap 202, by compression or friction fit or by glue, epoxy or similar adhesive. The optical fibers 203 are bundled together with the bottom fiber optic wire ends positioned substantially evenly as shown. The end surfaces of the optical fibers are positioned directly on top of the LED light 301. The LED 301 is electrically connected through the bottom of the housing 201 to the conductor subsystem 102. The conductor subsystem 102 is attached to the bottom of housing 201, which may also contain an internal resistor, a fuse, or other electrical elements.

FIG. 4 is a partially exploded, detailed perspective view of the fiber optic light array out of the LED housing for an individual fiber optic LED decoration light according to one embodiment of the present invention. The fiber optic LED decoration light units are manufactured and assembled similar to currently available incandescent Christmas tree light string, either in a parallel or single series wiring configuration. A deeper recess should be provided than for light sockets for incandescent bulbs, to allow the LED light 301 to be inserted deep into the housing 201 while providing sufficient space to insert the optical fibers into the housing 201 directly on top of the LED light 301 as shown in FIG. 3.

The LED light 301 may optionally have an integrated resistor at the base to allow multiple LED light string lengths equivalent to or greater than existing incandescent Christmas light strings. The LED string configuration can include all colors including red-green-blue (RGB), white, blue, green, red, orange and yellow, and can include blinking or non-blinking lights.

The optical fiber array consists of several bundled and unsheathed optical fibers held together by the cap housing with adhesives/glue, compression fitting or other binding mechanisms. The actual optical fibers may have the same or differing lengths. Pigmentation within the optical fibers may vary the output illumination, and interchangeable caps with different color optical fibers may be employed. Each cap may include only optical fibers of a single color, or may include optical fibers of different colors.

Once electrical wiring complete, the cap and optical fibers may be inserted in each housing 201. The cap 202 may be retained in the housing 201 either through a friction fit, rounded ridge and groover, and/or a plastic clip type mechanism to allow replacement if required.

The actual operation of the fiber optic LED decoration light string 100 is equivalent to existing incandescent Christmas lights by plugging into a standard household electrical outlet.

FIG. 5 is a close up view of an optional scratch/indentation pattern on the fiber optic wire to create a sparkling effect for an individual fiber optic LED decoration light according to one embodiment of the present invention. Scratches/indentations applied onto the individual fiber optic wire to create a sparkling pattern when light is transmitted through the fiber optic wire. The scratch or indentation can be uniform or randomly spaced.

The fiber optic LED decoration lights of the present invention uses the same wiring sequence (parallel or single series) of existing Christmas light strings, but replaces the incandescent light source(s) with a LED light source in conjunction with an optical fiber array to transmit the light into a radiant pattern. This modular design allows the user to enjoy the aesthetic beauty of fiber optic Christmas tree lights without the limiting factors of current designs, permitting decoration of any object that may be decorated using existing Christmas light strings with the visual benefit of optical fibers.

The present invention provides several advantages including: mobility and ease of use, with the strings adapted for use in numerous decorating environments; high energy efficiency relative to existing and equivalent incandescent light bulbs; virtually indestructible LED light source; low heat output providing reduced fire hazard; cost effective; and multiple color options and display (blinking or non blinking).

Although the present invention has been described in detail, those skilled in the art will understand that various changes, substitutions, variations, enhancements, nuances, gradations, lesser forms, alterations, revisions, improvements and knock-offs of the invention disclosed herein may be made without departing from the spirit and scope of the invention in its broadest form.

What is claimed is:

1. Fiber optic light emitting diode decoration lights comprising:
a plurality of light units electrically connected at spaced apart locations along a common electrical conductor, each light unit comprising:
an enclosure containing a light emitting diode; and
a plurality of optical fibers each having first and second ends, the optical fibers bundled at the first ends and having the second ends dispersed relative to each other, the optical fibers extending through the enclosure to positions proximate to the light emitting diode to receive light at the first ends from the light emitting diode, the light received from the light emitting diode emitted from the second ends of the optical fibers.

2. Fiber optic light emitting diode decoration lights according to claim 1, wherein the enclosure further comprises:
a housing receiving the light emitting diode; and
a cap fitting onto the housing and having the first ends of the optical fibers extending therethrough.

3. Fiber optic light emitting diode decoration lights according to claim 3, further comprising:
an opening through the cap through which the optical fibers extend.

4. Fiber optic light emitting diode decoration lights according to claim 1, wherein the first ends are positioned substantially evenly.

5. Fiber optic light emitting diode decoration lights according to claim 1, wherein two or more of the light units emit light of different colors selected from RGB, white, blue, green, red, orange and yellow.

6. Fiber optic light emitting diode decoration lights according to claim 1, wherein the light emitting diode within at least one of the light units is blinking.

7. Fiber optic light emitting diode decoration lights according to claim 1, wherein the light emitting diode within at least one of the light units is non-blinking.

8. Fiber optic light emitting diode decoration lights according to claim 1, wherein two or more of the optical fibers within at least one of the light units emit light of different colors.

9. Fiber optic light emitting diode decoration lights comprising:
a plurality of light units electrically connected at spaced apart locations along a common electrical conductor, each light unit comprising:
an enclosure containing a light emitting diode; and
a plurality of optical fibers each having first and second ends, each of the optical fibers extending through the enclosure with the first end thereof positioned proximate to the light emitting diode to receive light from the light emitting diode and the second end thereof dispersed relative to the second ends of others of the plurality of optical fibers, and
wherein the light received by the optical fibers from the light emitting diode at the first ends is emitted from the second ends of the optical fibers.

10. Fiber optic light emitting diode decoration lights according to claim 9, wherein the enclosure further comprises:
a housing receiving the light emitting diode; and
a cap fitting onto the housing and having the first ends of the optical fibers extending therethrough.

11. Fiber optic light emitting diode decoration lights according to claim 10, further comprising:
an opening through the cap through which the optical fibers extend.

12. Fiber optic light emitting diode decoration lights according to claim 9, wherein the first ends are positioned substantially evenly.

13. Fiber optic light emitting diode decoration lights according to claim 9, wherein two or more of the light units emit light of different colors selected from RGB, white, blue, green, red, orange and yellow.

14. Fiber optic light emitting diode decoration lights according to claim 9, wherein the light emitting diode within at least one of the light units is blinking.

15. Fiber optic light emitting diode decoration lights according to claim 9, wherein the light emitting diode within at least one of the light units is non-blinking.

16. Fiber optic light emitting diode decoration lights according to claim 9, wherein two or more of the optical fibers within at least one of the light units emit light of different colors.

17. A method of employing fiber optic light emitting diode decoration lights comprising:
providing electrical power to a plurality of light units electrically connected at spaced apart locations along a common electrical conductor, each light unit comprising:
an enclosure containing a light emitting diode, and
a plurality of optical fibers each having first and second ends, each of the optical fibers extending through the enclosure with the first end thereof positioned proximate to the light emitting diode and the second end thereof dispersed relative to the second ends of others of the plurality of optical fibers;
receiving light from each light emitting diode at the first end of one or more of the plurality of optical fibers extending through the enclosure containing the respective light emitting diode; and
emitting the received light from the second end thereof of at least some of those optical fibers receiving light at the first end thereof.

18. The method according to claim 17, further comprising:
receiving, from different light emitting diodes, light of different colors selected from RGB, white, blue, green, red, orange and yellow.

19. The method according to claim 19, further comprising one of:
providing electrical power to the plurality of light units such that at least one of the light units blinks; and
providing electrical power to the plurality of light units such that none of the light units blinks.

20. The method according to claim 19, further comprising:
providing electrical power to the plurality of light emitting diodes such that at least one of the light emitting diodes continues to emit light upon failure of another of the light emitting diodes.
